(19) United States
(12) Patent Application Publication
(10) Pub. No.: US 2012/0217894 A1
(43) Pub. Date: Aug. 30, 2012

(54) DRIVING CIRCUIT FOR LED

(75) Inventors: Charles Chang, Hsinchu County (TW); Ronald Chang, Hsinchu County (TW)

(73) Assignee: HANERGY TECHNOLOGIES, INC., Hsinchu County (TW)

(21) Appl. No.: 13/370,149

(22) Filed: Feb. 9, 2012

(30) Foreign Application Priority Data
Feb. 24, 2011 (TW) 100106295

(51) Int. Cl. H05B 41/282; H03K 3/017; G05F 1/10

(52) U.S. Cl. 315/265; 323/282; 327/172

(57) ABSTRACT

A driving circuit device for driving a load is provided. The driving circuit device includes a control module including a power correction module, and providing a control signal to adjust a current flowing through the load; and a pulse width modulation module being in cooperation with the power correction module to modulate the control signal, and including a voltage providing unit providing a pulse width modulation signal; and a Schmitt trigger circuit.

### CROSS-REFERENCE TO RELATED APPLICATION AND CLAIM OF PRIORITY

The application claims the benefit of Taiwan Patent Application No. 100106295, filed on Feb. 24, 2011, in the Taiwan Intellectual Property Office, the disclosures of which are incorporated herein in their entirety by reference.

### FIELD OF THE INVENTION

The present invention relates to a driving circuit, and more particularly to a driving circuit for an LED.

### BACKGROUND OF THE INVENTION

The LED is a common electronic element. At first, the LED only serves as the red pilot lamp. Then, the yellow-light LED, the orange-light LED, the green-light LED and the blue-light LED appear, which greatly expand the application range of the LED. Currently, the LED can be used for the traffic light, the lamp, the wall lamp, the LED array fluorescent lamp, etc. When the current is very low (approximately smaller than 20 mA), it is simpler to drive a single LED or a plurality of LEDs. When the power loss is not considered, the driving circuit can be achieved by using a simple linear regulator or a current-limiting resistor, wherein the current-limiting resistor can prevent the LED from burnout due to an excessively large current. However, a high-efficiency switching regulation circuit is usually used to prevent the power loss. LEDs connected in series also raise the variation range of the driving voltage, which increases the difficulty in designing the driving circuit.

The LED is a stable luminary, which can achieve a good and precise radiating color and intensity by providing a stable current and can reduce the rising temperature due to the energy consumption. Besides, the LED can meet the requirement of the green environmental protection and the electrical standards such as EN60598 of CE, EN61347 and EN60825. The driving circuit for the LED includes a control module. The control module includes a reference voltage, a current-sensing comparator, a ramp signal, an RS flip-flop, an oscillator and an LED driving gate. One important LED driving characteristic is the light-adjusting ability. The reference voltage and the ramp signal which is added with a feedback signal are input to the current-sensing comparator. The output signal from the current-sensing comparator and the signal from the oscillator are input to the RS flip-flop. The output signal from the RS flip-flop is input to the LED driving gate. The sensing current of the LED is controlled by the output signal from the LED driving gate, thereby determining the brightness of the LED.

A BUCK topology power supply includes the above-mentioned driving circuit for the LED, which can realize the current driving for the large-power LED and the array LED. Conventionally, for saving energy, a triac dimmer is disposed at the AC input terminal of the driving circuit for the LED to decrease the energy of the input wave. However, during the period when the energy of the input wave is decreased, the input signal of the control module of the driving circuit for the LED will suffer an unstable status of severe up-and-down vibration. This is difficult for the signal processing elements in the control module of the driving circuit for the LED to perform relevant operations to generate the control signal for driving the LED. Therefore, it is difficult for the driving circuit for the LED to provide a stable current to the LED in response to different topologies. Moreover, this buck topology also can use “the operation of fixing the turn-off time”. That is, the oscillator can start to count a fixed period when the output of the current-sensing comparator is rising. Besides, the ramp signal which is added with a current-sensing voltage, i.e. the feedback signal, can ease off the oscillation due to the operation at a fixed frequency.

In order to overcome the drawbacks in the prior art, a driving circuit for the LED is provided. The particular design in the present invention not only solves the problems described above, but also is easy to be implemented. Thus, the present invention has the utility for the industry.

### SUMMARY OF THE INVENTION

The present invention provides a method for driving the LED, which can drive the LED simply and efficiently, and is quite beneficial for the popularization of the LED.

The present invention provides a driving circuit for the LED. The prevent invention provides a pulse width modulation signal to the control module of the driving circuit, and reduces the noise of the driving circuit as well as enhances the driving effect thereof by using a stabilization circuit. The present invention uses a Schmitt trigger circuit to suppress the noise of the control signal stably. This not only enhances the matching of the electronic elements in the driving circuit, but also raises the brightness of the LED.

In accordance with an aspect of the present invention, a driving circuit device for driving a load is provided. The driving circuit device includes a control module including a power correction module, and providing a control signal to adjust a current flowing through the load; and a pulse width modulation module being in cooperation with the power correction module to modulate the control signal, and including a voltage providing unit providing a pulse width modulation signal; and a Schmitt trigger circuit.

In accordance with another aspect of the present invention, a pulse width modulation module is provided. The pulse width modulation module includes a voltage providing unit providing a pulse width modulation signal; and a stabilization circuit electrically connected to the voltage providing unit, and generating a limit value in response to the pulse width modulation signal.

In accordance with a further aspect of the present invention, a driving circuit device for driving a load is provided. The driving circuit device includes a control module including a power correction module, and providing a control signal to adjust a current flowing through the load; and a pulse width modulation module being in cooperation with the power correction module to modulate the control signal, and including a voltage providing unit providing a pulse width modulation signal; and a stabilization circuit.

In accordance with further another aspect of the present invention, a driving circuit device having a pulse width modulation signal is provided. The driving circuit device includes a stabilization circuit generating a limit value in response to the pulse width modulation signal.

The present invention provides a voltage providing unit providing a pulse width modulation signal; and a stabilization circuit electrically connected to the voltage providing unit, and generating a limit value in response to the pulse width modulation signal, wherein the limit value is an upper limit value or a lower limit value. This can efficiently avoid the noise due to the rapid variation of the signal. The present invention not only stabilizes the operation of the control module of the driving circuit, but also enhances the brightness of the LED and prolongs the life thereof.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 shows a driving circuit for the LED according to a first embodiment of the present invention; and

FIG. 2 shows a driving circuit for the LED according to a second embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

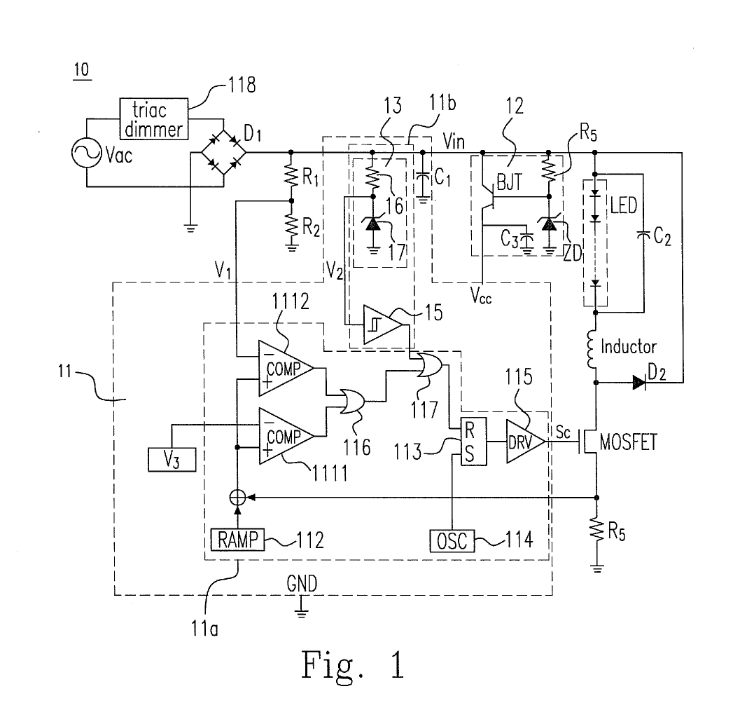

Please refer to FIG. 1, which shows a driving circuit 10 for the LED according to a first embodiment of the present invention. The driving circuit 10 includes a control module 11. The control module 11 includes a power correction module 11a and a pulse width modulation module 11b. The power correction module 11a provides a control signal S_{c} to adjust the current flowing through a load. The power correction module 11a includes a first comparator 1111, a second comparator 1112, a ramp signal 112, an RS flip-flop 113, an oscillator 114, a driving gate 115, a first OR gate 116 and a second OR gate 117. The pulse width modulation module 11b is in cooperation with the power correction module 11a to modulate the control signal S_{c}. The pulse width modulation module 11b includes a voltage providing unit 13 and a Schmitt trigger circuit 15. The voltage providing unit 13 provides a pulse width modulation signal V₂. The driving circuit 10 further includes a voltage clamping module 12 for providing a power voltage V_{cc} to the control module 11. Besides, the power correction module 11a performs a power factor function.

The voltage providing unit 13 includes a first resistor 16 and a Zener diode 17, which provide the pulse width modulation signal V₂. The Schmitt trigger circuit 15 receives the pulse width modulation signal V₂. The driving circuit 10 further includes a triac dimmer 118 for adjusting the waveform of an input signal. The load is an LED. The driving circuit 10 can be applied to a buck circuit topology, a buck-boost circuit topology and a floating ground buck circuit topology.

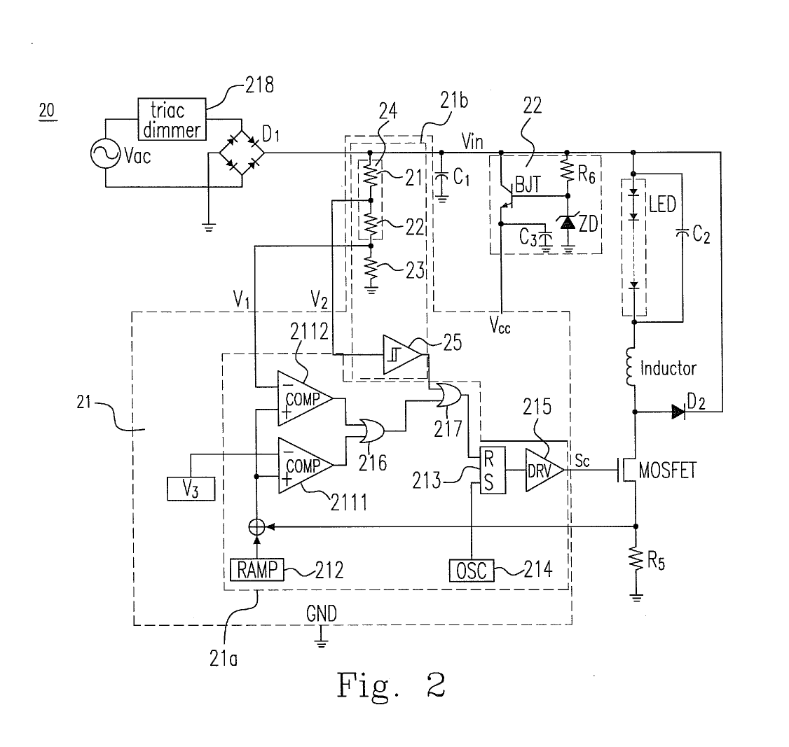

Please refer to FIG. 2, which shows a driving circuit 20 for the LED according to a second embodiment of the present invention. The driving circuit 20 includes a control module 21. The control module 21 includes a power correction module 21a and a pulse width modulation module 21b. The power correction module 21a provides a control signal S_{c} to adjust the current flowing through a load. The power correction module 21a includes a first comparator 2111, a second comparator 2112, a ramp signal 212, an RS flip-flop 213, an oscillator 214, a driving gate 215, a first OR gate 216 and a second OR gate 217. The pulse width modulation module 21b is in cooperation with the power correction module 21a to modulate the control signal S_{c}. The pulse width modulation module 21b includes a voltage providing unit 24 and a Schmitt trigger circuit 25. The voltage providing unit 24 provides a pulse width modulation signal V₂. The driving circuit 20 further includes a voltage clamping module 22 for providing a power voltage V_{cc} to the control module 21. Besides, the power correction module 21a performs a power factor function.

The voltage providing unit 24 includes a first resistor 21, a second resistor 22 and a third resistor 23, which provide a first voltage V₁ and the pulse width modulation signal V₂ simultaneously. The Schmitt trigger circuit 25 receives the pulse width modulation signal V₂. The driving circuit 20 further includes a triac dimmer 218 for adjusting the waveform of an input signal. The load is an LED. The driving circuit 20 can be applied to a buck circuit topology, a buck-boost circuit topology and a floating ground buck circuit topology.

The present invention compensates the shortcomings of the prior art by providing the pulse width modulation signal V₂. The control module 11 of the driving circuit 10 of FIG. 1 includes the pulse width modulation module 11b for providing the pulse width modulation signal V₂, and the control module 21 of the driving circuit 20 of FIG. 2 includes the pulse width modulation module 21b for providing the pulse width modulation signal V₂.

The addition of the pulse width modulation signal V₂ to the control module 11, 21 of the driving circuit 10, 20 can be applied to different control modules of the driving circuits and different driving topologies for the LED. The present invention performs the power factor correction function to enhance the utilization rate of the electrical energy, and reduces the noise and increases the performance of the circuit by adding the feedback signal, thereby reducing the rising temperature due to the energy consumption and enhancing the ability of anti-electromagnetic interference. The present invention can convert the AC power into the DC power for driving the large-power LED and the array LED by adding the pulse width modulation module 11b, 21b, which can not only achieve a good and precise radiating color and intensity by enhancing the reliability of the driving signal, but also be applied to the LED array fluorescent lamp and other photoelectric light-emitting elements driven in a circuit-driving way. Moreover, the present invention can also enhance the efficiency of the driving circuit and achieve the goal of saving energy.

### Embodiments

1. A driving circuit for driving a load, comprising:
a control module including a power correction module, and providing a control signal to adjust a current flowing through the load; and
a pulse width modulation module being in cooperation with the power correction module to modulate the control signal, and including:
   a voltage providing unit providing a pulse width modulation signal; and
   a Schmitt trigger circuit.

2. The driving circuit of Embodiment 1, further comprising:
a voltage clamping module providing a power voltage to the control module.

3. The driving circuit of any one of Embodiments 1-2, wherein the power correction module performs a power factor correction.

4. The driving circuit of any one of Embodiments 1-3, wherein the voltage providing unit comprises a first resistor, a second resistor and a third resistor which provide a first voltage and the pulse width modulation signal simultaneously.

5. The driving circuit of any one of Embodiments 1-4, wherein the voltage providing unit comprises a fourth resistor and a Zener diode which provide the pulse width modulation signal.

6. The driving circuit of any one of Embodiments 1-5, wherein the Schmitt trigger circuit receives the pulse width modulation signal.

7. The driving circuit of any one of Embodiments 1-6, further comprising:
a triac dimmer adjusting a waveform of an input signal.

8. The driving circuit of any one of Embodiments 1-7, wherein the load includes an LED.

9. The driving circuit of any one of Embodiments 1-8, being applied to one selected from a group consisting of a buck circuit topology, a buck-boost circuit topology and a floating ground buck circuit topology.

10. A pulse width modulation module, comprising:
a voltage providing unit providing a pulse width modulation signal; and
a stabilization circuit electrically connected to the voltage providing unit, and generating a limit value in response to the pulse width modulation signal.

11. The pulse width modulation module of Embodiment 10, wherein the voltage providing unit comprises a first resistor, a second resistor and a third resistor which provide a first voltage and the pulse width modulation signal simultaneously.

12. The pulse width modulation module of any one of Embodiments 10-11, wherein the voltage providing unit comprises a fourth resistor and a Zener diode which provide the pulse width modulation signal.

13. The pulse width modulation module of any one of Embodiments 10-12, wherein the limit value is one of an upper limit value and a lower limit value.

14. The pulse width modulation module of any one of Embodiments 10-13, wherein the stabilization circuit receives the pulse width modulation signal.

15. The pulse width modulation module of any one of Embodiments 10-14, wherein the stabilization circuit includes a Schmitt trigger circuit.

16. A driving circuit for driving a load, comprising:
a control module including a power correction module, and providing a control signal to adjust a current flowing through the load; and
a pulse width modulation module being in cooperation with the power correction module to modulate the control signal, and including:
   a voltage providing unit providing a pulse width modulation signal; and
   a stabilization circuit.

17. The driving circuit of Embodiment 16, wherein the stabilization circuit includes a Schmitt trigger circuit.

18. The driving circuit of any one of Embodiments 16-17, wherein the stabilization circuit receives the pulse width modulation signal.

19. A driving circuit having a pulse width modulation signal, comprising:
a stabilization circuit generating a limit value in response to the pulse width modulation signal.

20. The driving circuit of Embodiment 19, wherein the stabilization circuit receives the pulse width modulation signal.

21. The driving circuit of any one of Embodiments 19-20, wherein the stabilization circuit includes a Schmitt trigger circuit.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A driving circuit for driving a load, comprising:
a control module including a power correction module, and providing a control signal to adjust a current flowing through the load; and
a pulse width modulation module being in cooperation with the power correction module to modulate the control signal, and including:
a voltage providing unit providing a pulse width modulation signal; and
a Schmitt trigger circuit.

2. A driving circuit as claimed in claim 1, further comprising:
a voltage clamping module providing a power voltage to the control module.

3. A driving circuit as claimed in claim 1, wherein the power correction module performs a power factor correction.

4. A driving circuit as claimed in claim 1, wherein the voltage providing unit comprises a first resistor, a second resistor and a third resistor which provide a first voltage and the pulse width modulation signal simultaneously.

5. A driving circuit as claimed in claim 1, wherein the voltage providing unit comprises a fourth resistor and a Zener diode which provide the pulse width modulation signal.

6. A driving circuit as claimed in claim 1, wherein the Schmitt trigger circuit receives the pulse width modulation signal.

7. A driving circuit as claimed in claim 1, further comprising:
a triac dimmer adjusting a waveform of an input signal.

8. A driving circuit as claimed in claim 1, wherein the load includes an LED.

9. A driving circuit as claimed in claim 1, being applied to one selected from a group consisting of a buck circuit topology, a buck-boost circuit topology and a floating ground buck circuit topology.

10. A pulse width modulation module, comprising:
a voltage providing unit providing a pulse width modulation signal; and
a stabilization circuit electrically connected to the voltage providing unit, and generating a limit value in response to the pulse width modulation signal.

11. A pulse width modulation module as claimed in claim 10, wherein the voltage providing unit comprises a first resistor, a second resistor and a third resistor which provide a first voltage and the pulse width modulation signal simultaneously.

12. A pulse width modulation module as claimed in claim 10, wherein the voltage providing unit comprises a fourth resistor and a Zener diode which provide the pulse width modulation signal.

13. A pulse width modulation module as claimed in claim 10, wherein the limit value is one of an upper limit value and a lower limit value.

14. A pulse width modulation module as claimed in claim 10, wherein the stabilization circuit receives the pulse width modulation signal.

15. A pulse width modulation module as claimed in claim 10, wherein the stabilization circuit includes a Schmitt trigger circuit.

16. A driving circuit for driving a load, comprising:
a control module including a power correction module, and providing a control signal to adjust a current flowing through the load; and
a pulse width modulation module being in cooperation with the power correction module to modulate the control signal, and including:
a voltage providing unit providing a pulse width modulation signal; and
a stabilization circuit.

17. A driving circuit as claimed in claim 16, wherein the stabilization circuit includes a Schmitt trigger circuit.

18. A driving circuit as claimed in claim 16, wherein the stabilization circuit receives the pulse width modulation signal.

19. A driving circuit having a pulse width modulation signal, comprising:
a stabilization circuit generating a limit value in response to the pulse width modulation signal.

20. A driving circuit as claimed in claim 19, wherein the stabilization circuit receives the pulse width modulation signal.

21. A driving circuit as claimed in claim 19, wherein the stabilization circuit includes a Schmitt trigger circuit.
